(19) United States
(12) Patent Application Publication
(10) Pub. No.: US 2006/0056241 A1
(43) Pub. Date: Mar. 16, 2006

(54) Artificial aging of chips with memories

(76) Inventors: Juergen Auge, Unterhaching (DE); Helmut Fischer, Oberhaching (DE); Manfred Proell, Dorfen (DE); Stephan Schroeder, Munich (DE)

Correspondence Address: SLATER & MATSIL LLP, 17950 PRESTON ROAD, SUITE 1000, DALLAS, TX, 75252, US

(21) Appl. No.: 11/225,864

(22) Filed: Sep. 13, 2005

(30) Foreign Application Priority Data
Sep. 13, 2004 (DE) 10 2004 044 150.2

(51) Int. Cl. G11C 7/10; G11C 5/06

(52) U.S. Cl. 365/189.01; 365/63

(57) ABSTRACT

An apparatus for aging a chip, comprising a first bit line connected to a first memory cell; a second bit line connected to a second memory cell; an access circuit for accessing the first memory cell via the first bit line and for accessing the second memory cell via the second bit line; a first controller for selectively connecting/disconnecting the first bit line to the access circuit and from the access circuit, respectively; a second controller for selectively connecting/disconnecting the second bit line to the access circuit and from the access circuit, respectively; a normal operating mode controller for controlling the first and second controller, wherein the normal operating mode controller is formed such to select the first controller in a normal operating mode for accessing the first memory cell, and to connect the access circuit to the first bit line, while the second controller is controlled to disconnect the access circuit from the second bit line; wherein the apparatus comprises: an aging mode controller for controlling the first and second controller, wherein the aging mode controller is formed to control the first controller and the second controller in an aging mode such that the access circuit is connected to the first and second bit lines for a predetermined time period.

This application claims priority from German Patent Application No. 10 2004 044 150.2, which was filed on Sep. 13, 2004 and is incorporated herein by reference in its entirety.

### TECHNICAL FIELD

The present invention relates to an apparatus and a method for improving artificially generated aging processes of chips.

### BACKGROUND

In the production of chips, such as memory components, alterations of the electrical parameters can occur during an operating time of the chips, for example, due to weaknesses in the manufacturing process. In the present invention, a chip is a semiconductor die comprising an arrangement of circuits.

For that reason, the chips are artificially pre-aged by a so-called burn-in prior to reaching a customer. By artificial pre-aging, early failures are already provoked and sorted out prior to delivering to the customer. Thus, all in all, an improvement of the early failure rates at the customer occurs through the saturation behavior of the early failures. In order to perform pre-aging efficiently, corresponding acceleration factors are used for different early failure mechanisms. Normally, these are higher voltages and higher temperatures as well as a more effective clock ratio between an inactive and an active state.

Several memory cells present on the chip can be connected such that a read amplifier accesses a configuration of one or several memory cells via a bit line. The read amplifier, which can, for example, be designed as a sense amplifier, detects the cell signal transmitted via the bit line and/or amplifies the same. An amplified signal can then, on the one hand, be written back to a cell via the bit line and, on the other hand, be read out to the exterior. In the chip, for example, a control means controls several switches such that only a single bit line is connected to the access means during a certain time period of the read or write process. During the process of artificially generated aging the chip, the control means controls the switches such that several bit lines going out from the read amplifier are connected to the same one after the other. The other bit lines going out from the read amplifier, which are not selected, are disconnected from the read amplifier. Thus, during artificial aging in normal read/write processes, only a single bit line is connected to the read amplifier. This procedure, that only one of the bit lines going out from the read amplifier can be connected to the same by the switches for a predetermined time period, leads to the fact that the artificially generated aging process is prolonged when a predetermined aging is to be achieved, or that the artificially generated aging is reduced when the time period for the aging process is fixed.

### SUMMARY OF THE INVENTION

In one aspect, the present invention provides a chip, which enables an improved artificially generated aging process, and a method for an improved artificially generated aging process.

In accordance with a first aspect, the present invention provides an apparatus for aging a chip. A first bit line is connected to a first memory cell. A second bit line is connected to a second memory cell. An access circuit accesses the first memory cell via the first bit line and the second memory cell via the second bit line. A first controller selectively connects and/or disconnects the first bit line to the access circuit and from the access circuit, respectively. A second controller selectively connects/disconnects the second bit line to the access circuit and from the access circuit, respectively. A normal operating mode controller controls the first and second controller, wherein the normal operating mode controller is formed such to select the first controller in a normal operating mode for accessing the first memory cell, and to connect the access circuit to the first bit line, while the second controller is controlled to disconnect the access circuit from the second bit line; wherein the apparatus has an aging mode controller for controlling the first and second controller, wherein the aging mode controller is formed to control the first controller and the second controller in an aging mode such that the access circuit is connected to the first and second bit lines for a predetermined time period.

In accordance with a second aspect, the present invention provides a method for aging a chip. A first bit line is connected to a first memory cell. A second bit line is connected to a second memory cell. An access circuit accesses the first memory cell via the first bit line and the second memory cell via the second bit line. A first controller selectively connects and/or disconnects the first bit line to the access circuit and from the access circuit, respectively. A second controller selectively connects/disconnects the second bit line to the access circuit and from the access circuit, respectively. A normal operating mode controller controls the first and second controller, wherein the normal operating mode controller is formed such to select the first controller in a normal operating mode for accessing the first memory cell, and to connect the access circuit to the first bit line, while the second controller is controlled to disconnect the access circuit from the second bit line; wherein the method has the step of selecting an aging mode controller for controlling the first and second controller, so that the first and second controller are selected such that the access circuit is connected to the first and second bit lines for a predetermined time period.

In accordance with a third aspect, the present invention provides a computer program with a program code for performing the method for aging a chip. A first bit line is connected to a first memory cell. A second bit line is connected to a second memory cell. An access circuit accesses the first memory cell via the first bit line and the second memory cell via the second bit line. A first controller selectively connects and/or disconnects the first bit line to the access circuit and from the access circuit, respectively. A second controller selectively connects/disconnects the second bit line to the access circuit and from the access circuit, respectively. A normal operating mode controller controls the first and second controller, wherein the normal operating mode controller is formed such to select the first controller in a normal operating mode for accessing the first memory cell, and to connect the access circuit to the first bit line, while the second controller is controlled to disconnect the access circuit from the second bit line; wherein the method has the step of selecting an aging mode controller for controlling the first and second controller, so that the first and second controller are selected such that the access circuit is connected to the first and second bit lines for a predetermined time period, when the computer program runs on a computer.

In a preferred embodiment, the present invention implements a burn-in mode control mechanism on the chip. This burn-in mode control mechanism controls the controller such that several bit lines going out from an access circuit are simultaneously connected to the access circuit for a predetermined time period.

It is an advantage of the present invention that several bit lines going out from an access circuit can be stressed at the same time and that thereby the time period for the aging process can be accelerated when the scale of the artificially generated aging is predetermined. The disadvantage of the additional implementing effort is significantly surpassed by the advantage of reducing the burn-in effort. A further advantage results when the time period for the artificially generated aging process is fixed, in that thereby a number of the artificially generated early failures increases and a number of early failures of chips delivered to the customer is reduced. Thus, the quality of the delivered chips is improved.

In other words, it is the object of the invention to make the stress between the bit lines going out from the access circuit more effective. Therefore, during the burn-in mode, the clock ratio between the active and inactive state of the bit line is increased compared to a regular access in the operating mode.

### DESCRIPTION OF THE DRAWINGS

These and other objects and features of the present invention will become clear from the following description taken in conjunction with the accompanying drawings, in which:

FIG. 1 is a section of a structure of a memory field of a chip of the present invention;

FIG. 2 is a more detailed section of the structure of a chip of the present invention;

FIG. 3a is a waveform of the voltages in an operating mode; and

FIG. 3b is a waveform of the voltages in a burn-in mode.

### DETAILED DESCRIPTION OF ILLUSTRATIVE EMBODIMENTS

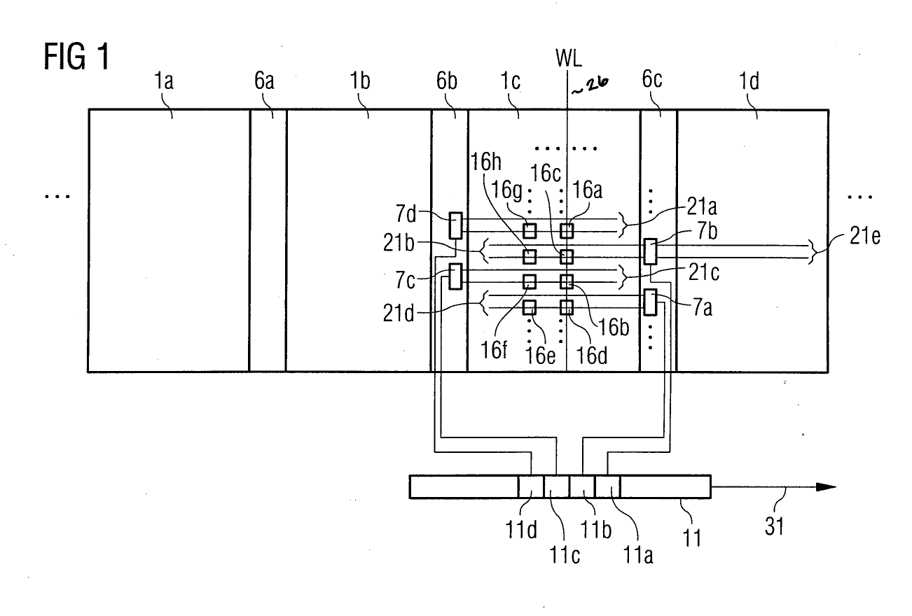

FIG. 1 shows a section of a block diagram of a chip according to an embodiment of the present invention. The block diagram shows exemplarily blocks 1a-d of a memory field of the DRAMs, wherein, however, any number of memory blocks could be provided in the DRAM. Between the blocks, three stripes 6a-c of read amplifiers 7a-d are disposed. Additionally, the DRAM comprises a buffer 11 for output data. Every block 1a-d comprises several memory cells disposed in columns and rows, bit line pairs running along the columns and word lines running along the rows, wherein exemplarily and for clarity reasons merely eight memory cells 16a-h, four bit line pairs 21a-d and one word line 26 are shown in block 1c and one bit line pair 21e in the block 1d of the memory field. The stripes 6a-c for read amplifiers 7a-d include one read amplifier, such as the read amplifier 7b for the bit line pairs 21e and 21b, for every pair of adjacent bit line pairs of the two respective adjacent blocks, which are associated and run away from each other. Additionally, exemplarily the read amplifiers 7c, 7d of the strip 6b and the read amplifiers 7a, 7b of the strip 6c are shown, which are connected to the illustrated bit line pairs 21a-e. The buffer 11 for output data consists of cells 11a-d of the buffer 11 and an output data bus 31.

The word line 26 is applied to a sequence of memory cells 16a-d disposed along a row of block 1c, wherein, as mentioned, the four cells 16a-d are shown in this embodiment only exemplarily for all memory cells connected to the word line 26. The bit line pairs 21a-d are connected to memory cells disposed along a column and are each connected to one of the read amplifiers 7a-d. The bit line pair 21e, which is part of block 1d, is also connected to the read amplifier 7b. Outputs of the read amplifiers 7a-d are each connected to an input of a cell 11a-d of the buffer 11, while the output data bus 31 is connected to the output of the buffer 11 for outputting read-out data to, for example, a CPU (not shown).

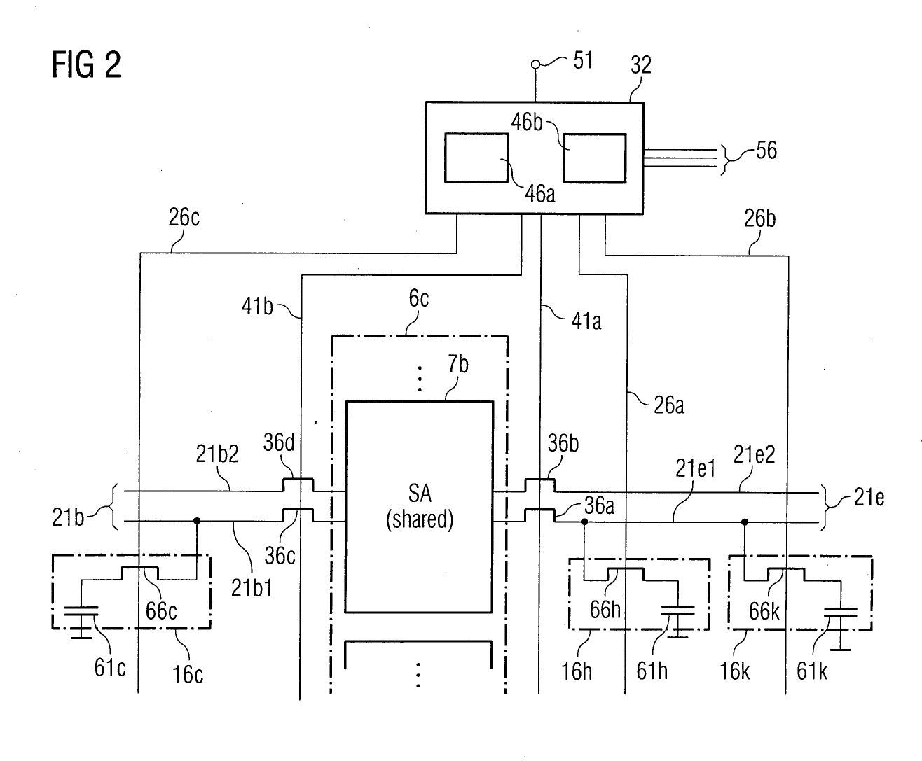

After the structure of a chip of FIG. 1 has been described above, its mode of operation during normal operation will be described below. When the CPU obtains a request for access to a certain memory address, it selects the word line 26 corresponding to this address. The block 1a-d, in which this word line resides, is referred to as active block. The other blocks are deactivated in the meantime, wherein the corresponding means will be discussed in more detail below with reference to FIG. 2. For example, it is assumed that the word line 26 is selected. Then, the word line 26 selects the memory cells 16a-d such that the read amplifiers 7a-d read out the content of the memory cells 16a-d via the bit line pairs 21a-d. The read amplifiers 7a-d forward the data acquired that way to the cells 11a-d of the buffer 11. Then, this buffer puts the data on the output data bus 31, from where they are read out, for example, by an external device (not shown).

The mode of operation of the above chip during burn-in according to an embodiment of the present invention will be discussed below with reference to FIG. 2.

FIG. 2 shows a detailed section of the chip of FIG. 1 according to an embodiment of the present invention. Particularly, FIG. 2 shows the access circuit 7b of strip 6c, the memory cell 16c of block 1c, further memory cells 16h, 16k of the adjacent block not illustrated in FIG. 1, the bit line pairs 21b, 21e, word lines 26a-c, a controller 32, field-effect transistors 36a-d and selection lines 41a, 41b. The controller 32 comprises an operating mode controller 46a, a burn-in mode control mechanism 46b, a terminal 51 for mode selection and an address data bus 56. The bit line pair 21b consists of bit lines 21b1 and 21b2, while the bit line pair 21e consists of bit lines 21e1 and 21e2. The memory cells 16c, 16h, 16k each consist of a capacitance 61c, 61h, 61k and a transistor switch 66c, 66h, 66k. The bit line pair 21b, which is conductively connected to the memory cell 16c for reading out the memory content is conductively connected to the read amplifier 7b via the field-effect transistors 36c-d. The bit line pair 21e, to which the memory cells 16h, 16k are associated, is conductively connected to the read amplifier 7b via the transistor switches 36a, 36b. The word lines 26a-c are applied to the output of the controller 32 and control the transistor switches 66c, 66h, 66k. The capacitances 61c, 61h, 61k are conductively connected to the bit lines 21b1, 21e1 via the transistor switches 66c, 66h, 66k.

First, the mode of operation of the switch of FIG. 2 will be described with reference to the normal operating mode. The controller 32 receives via the address data bus 56 information about the unit to be addressed and a word to be addressed, respectively, which is to be stored in a memory cell lying in one row. It converts this information in the operation mode controller 46a and then activates one of the word lines 26a-c. Simultaneously, it selects the field-effect transistors 36a-d via the selection lines 41a, 41b. A signal applied to the terminal 51 for mode selection determines whether processing the address data will be performed in the operation mode controller 46a or the burn-in controller 36b and whether the normal operation mode or the burn-in mode is present, respectively.

a) Mode of Operation:

A selection of an operating mode is performed by a signal at the terminal 51. In the operating mode, processing of the address data is performed in the operating mode controller 46a. This determines which of the word lines 26a-c is to be activated, based on the address data of the memory cell 16c, 16h, 16k. Additionally, it determines via a signal on the selection lines 41a, 41b, which of the two bit line pairs 21b, 21e is to be conductively connected or disconnected, respectively, to the read amplifiers 7b in the strips 6c, which are adjacent to the block wherein the selected bit line is, i.e., the active block, via the field-effect transistors 36a-d. Particularly, this is performed such that only those bit line pairs are connected to the read amplifiers of the stripes adjacent to the active block, which are in the active block. If, for example, one of the two word lines 26a, 26b is activated, which means block 1d (FIG. 1) is the active block, then the transistors 36a, 36b are informed via a signal on the selection line 41a that the same are to connect the bit line pair 21e conductively to the read amplifier 7b. At the same time, the controller 32, wherein the normal operating mode controller 36a is activated, informs the field-effect transistors 36c, 36d that the bit line pair 21b is to be disconnected from the read amplifier 7b, since the word line 26c, which is the only word line on the left of the read amplifier 7b in this embodiment, is not activated and this block is inactive, respectively.

In the following, exemplarily, a read-out process from the memory cell 16k will be discussed in more detail. Therefore, the word line 26b is activated. It controls the transistor 66k such that it conductively connects the capacitance 61k to the bit line 21e1. The bit line 21e2, whose length is of the same order of magnitude as the one of the bit line 21e1, also has a capacitance with the same order of magnitude. The capacitance of the bit line 21e2 is often referred to as reference capacitance. During the read out process, the read amplifier 7b sees an interconnection between the capacitances of the bit lines 21e1, 21e2 and the capacitance 61k. In this arrangement, the bit lines 21e1, 21e2 are connected such that they compensate each other and the read amplifier 7b can thereby detect a load state of the capacitance 61k more easily.

b) Burn-In Mode

By a signal at the terminal 51 for mode selection, the burn-in mode controller 46b is activated in the controller 32. In that mode, the controller 32 and 46b, respectively, activates all bit lines according to a predetermined sequence. If a word line, such as the word line 26b, is activated, the controller 46b informs the field-effect transistors 46a, 46b via the selection line 41a that they are to connect the bit line pair 21e conductively to the read amplifier 7b. At the same time, it informs the field-effect transistors 36c, 36d at least during part of the time period when the bit line pair 21e is conductively connected to the read amplifier 7b via the selection line 41d, that they are to conductively connect also the bit line pair 21b to the read amplifier 7b. Thereby, the bit line pair 21b is conductively connected to the read amplifier 7b in a predetermined time period, where it would otherwise be disconnected from the read amplifier 7b, when the selection was performed via the operating mode controller 46a and not via the burn-in mode controller 46b. This leads to additional stress and load, respectively, and thus to artificial aging of the bit line pair 21b, which would otherwise not take place in the operating mode.

The consequences of this burn-in mode can be discussed for a certain batch of chips with regard to cases a) and b). The batch has to consist of an amount of 100,000 units, which would show 60 early failures in an aging process performed via the operating mode, and 20 early failures at the customer within a first half year, during which the customer uses the units. In scenario a), where the artificially generated aging is performed in the burn-in mode over the same time period as in the operating mode, now 70 units fail during the artificially generated aging process and there will be only 10 failures at the customer within the first half year through the usage of the burn-in mode and the corresponding selection of the burn-in mode controller 46b. Thus, the quality of the delivered products has improved.

In case b), the time during which the batch passes through the artificially generated aging process, is reduced, for example, from 1,000 hours to 500 hours. During these 500 hours again 60 early failures result, since the units are stressed more intensely in these 500 hours. Here, also 20 units fail in the first half year at the customer. The quality of the delivered units has remained constant compared to an artificially generated aging process in the operating mode, but the time for the artificially generated aging process could be halved and thus the cost could be reduced significantly.

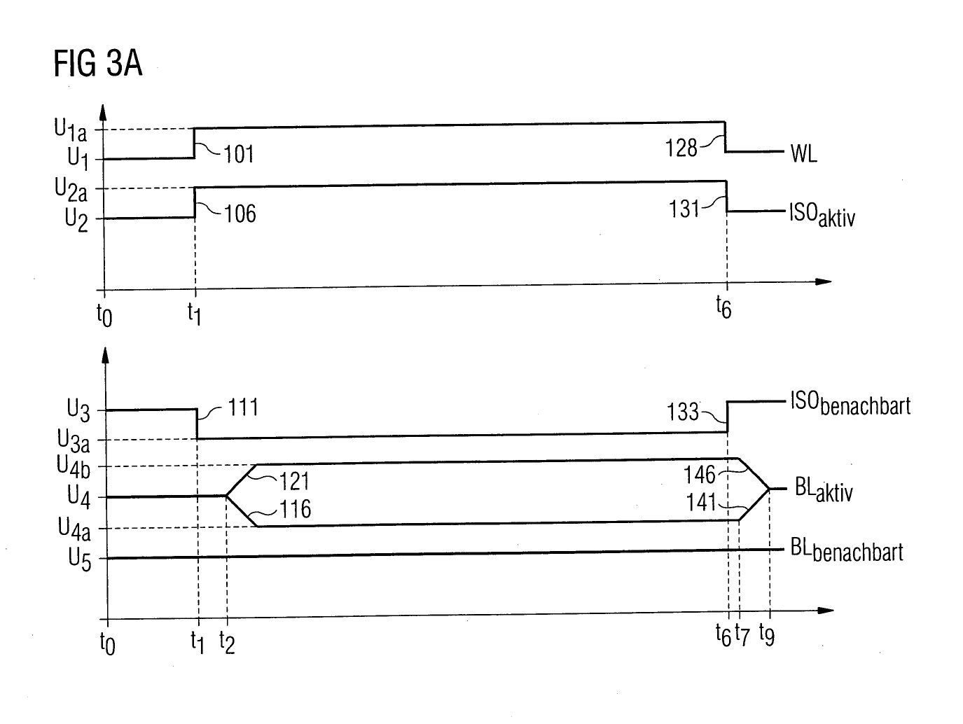

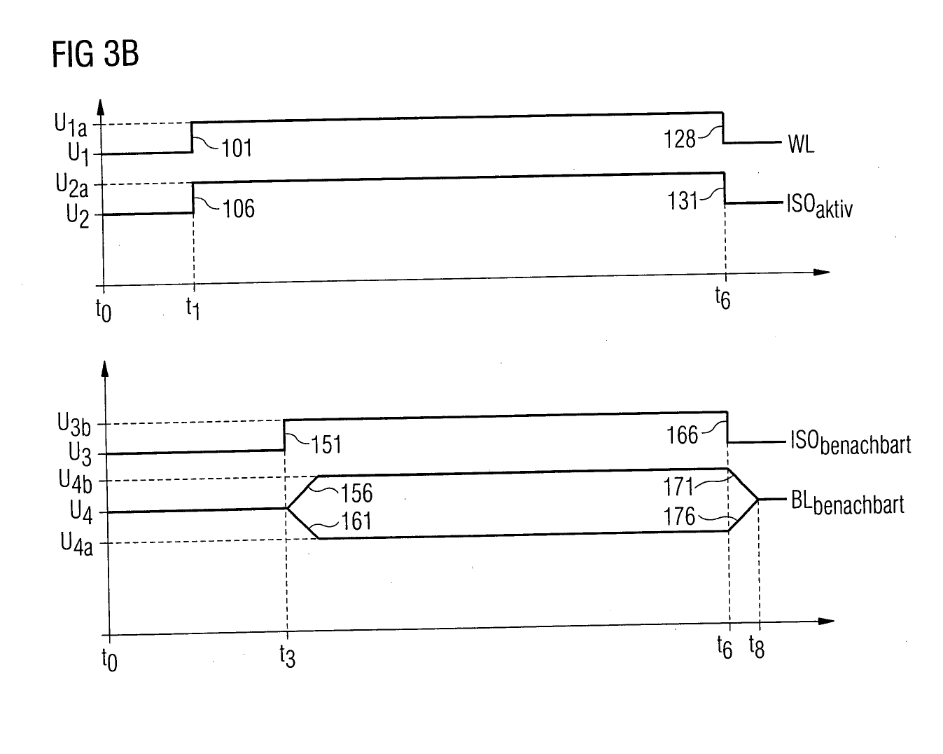

FIG. 3a shows exemplary waveforms at dedicated lines according to an embodiment of the present invention for illustrating the selection of the memory element 16k in the normal operating mode in more detail.

A top diagram of FIG. 3a, where the time is plotted along the x-axis and the voltage along the y-axis in arbitrary units, shows a waveform of a signal WL at the word line 26b and a signal ISO_{active} at the selection line 41a. At a time t₀, the two lines are on their output voltages U₁, U₂. At a time t₁, the voltage on the word line 26b, which is illustrated as signal WL in the top diagram, is raised by a certain value to the level U₁ₐ. This result is illustrated in the diagram by an edge 101. At the time t₁, the selection line 41a is also activated in parallel to the word line 26b. It is then raised from the output level U₂ by a certain value to the level U₂ₐ, which is illustrated in an edge 106. At a time t₆, the read-out process from the memory cell 16k is terminated. Therefore, the signal WL on the word line 26b is reduced from the value U₁ₐ to the output level at the time t₀ U₁, which is illustrated by an edge 128. Thereby, the word line 26b is deactivated and the capacitance 61k is disconnected from the bit line pair 21e by the transistor switch 66k. Simultaneously, at the time t₆, the bit line pair 21e is disconnected from the read amplifier 7b, by reducing the voltage on the selection line 41a from the value U₂ₐ to its output value, the value at the time t₀. This is illustrated in an edge 131.

In a bottom diagram of FIG. 3a, where the time is plotted along the x-axis and the voltage along the y-axis in arbitrary units, a waveform ISO_{adjacent} is illustrated on the selection line 41b, as it is generated by the normal operating mode control 46b. As has already been mentioned, all waveforms represented in this diagram relate to a configuration in the controller 36 where the operating mode controller 46a is selected by the terminal 51. A voltage on the selection line 41b is U₃ at a time t₀, and is lowered by a certain value to the level U₃ₐ at the time t₁, which is illustrated in edge 111. This informs the field-effect transistors 36c, 36d that the disconnection of the bit line pair 21b from the read amplifier 7b is to be maintained during the read out process of the memory cell 16k via the bit line pair 21e. At a time t₆, the voltage at the selection line 41b is raised by a predetermined value, so that it reaches again the initial level U₃, that it already had at a time t₀. During the whole time period, the bit line pair 21b is disconnected from the read amplifier 7b by the field-effect transistors 36c, 36d. Thus, the voltage on the bit lines 21b1, 21b2 remains constant on an initial level U₅ during the whole time period, from the time t₀ to a time t₉ when the whole read out process is completed in the active field, which means from the memory cell 16k.

In the bottom diagram of FIG. 3a, the voltage on the bit line pair 21e, BL_{active} is illustrated, which results due to the signals WL, ISO_{active} and ISO_{adjacent} set by the control 46a. The bit line 21e1 tilts from an initial level U₄ at a time t₂, which is after the time t₁, either towards the bottom, which is illustrated in an edge 116, when a low charge state is present on the capacitance 61k, or towards the top, which is illustrated in an edge 121, when a high charge state is present on the capacitance 61k. The bit line 21e2 behaves exactly inverse to 21e1. A voltage difference is formed between 21e1 and 21e2.

At a time t₇, the voltage between the bit line pair 21e starts to return to its initial level U₄ via edges 141 or 146, which is terminated at a time t₉.

FIG. 3b shows an exemplary waveform at the lines of FIG. 3a, when the burn-in mode controller 46b is active in the controller 32, and this selection has been made by a corresponding signal at the terminal 51.

In a top diagram of FIG. 3b, where the time is plotted along the x-axis and the voltage along the y-axis in arbitrary units, again, the waveform WL is illustrated at a word line 26b WL and the waveform ISO_{active} at a selection line 41a. It can be seen that the waveform WL on the word line 26b and ISO_{active} on the selection line 41a have not changed compared to the normal operating mode, which is illustrated in FIG. 3a in the top diagram.

A bottom diagram of FIG. 3b, where the time is plotted along the x-axis and the voltage along the y-axis in arbitrary units, shows the voltage curve at the bit line pair 21b, BL_{adjacent} and on the selection line 41b ISO_{adjacent}. Here, it can be seen that at a time t₃, the signal on the selection line 41b is raised from an initial value U₃ by a certain value to a level U_{3b}, which is illustrated in an edge 151. This signal leads to the bit line pair being conductively connected to the read amplifier 7b while the bit line pair 21e is also conductively connected to the read amplifier 7b. On the bit line pair 21b BL_{adjacent}, from t₃ onwards, the same voltage ratios occur as in the bit line pair 21e, BL_{active}. At the time t₆, the voltage on the selection line 41b is reset from the level U_{3b} by a certain value to the initial level U₃, which is illustrated in an edge 166. This leads to disconnecting the bit line pair 21b from the read amplifier 7b. Thus, at a time t₈, when the voltage between the bit line pair 21b has fully returned to the initial level U₄, the bit line pair 21b is also disconnected from the read amplifier 7b. By the different curve of the signal BL_{adjacent} in the bottom diagram of FIG. 3b compared to the bottom diagram of FIG. 3a, it can be seen that the bit line pair 21b in the burn-in mode experiences additional stress. This additional stress leads again to an improved artificially aging of the chip.

For explanation purposes, only relatively few memory cells are mentioned in the above embodiments. The number of memory cells in the blocks in common chips can of course be up to several millions, which also leads to the fact that the number of bit line pairs and word line pairs in a block in commercial chips can be up to an order of magnitude of several thousands. Also, the field-effect transistors 36a-d can be designed as arbitrary controllable circuit elements, such as bipolar circuit elements or even tyristors, etc. The transistor switches 66a-c can also be designed as arbitrary circuit elements. The arrangement of the bit line pairs 21b, 21e and their number can also be varied arbitrarily. For example, bit line pairs can go out radially from the read amplifier 7b, which are stressed in a different way in the burn-in mode and the operating mode.

The memory cells mentioned in these embodiments can also be DRAM memory cells, SRAM memory cells, EEPROM memory cells, ROM memory cells or EPROM memory cells.

Thus, the above embodiments describe a DRAM where the memory field of DRAM consists of rows along which the word lines 26, 26a-d extend and columns along which the bit lines 21a-e extend. In a memory access, first, a word line 26, 26a-c is activated. Thereby, the memory cells arranged in one row are connected to one bit line. At the end of the bit line is a read amplifier 7a-d which can be designed as sense amplifier and detects and amplifies the cell signal transmitted via the bit line. The amplified signal is, on the one hand, written back via the bit line into the cell and can, on the other hand, be read out to the exterior. The process described herein is performed simultaneously for all cells disposed in one word line. This means also that after the activation all bit lines are provided with a signal.

In order to achieve an arrangement of the cell field, which is as compact as possible, bit lines, which are as long as possible, are desirable. However, on the other hand, this leads to a reduction of the signal to be detected by the read amplifier. Thus, in one embodiment of a commercial chip, it is possible to divide the cell field of a DRAM into individual blocks. In order to save space, the stripe for read amplifiers 6a-c disposed between two cell field blocks is used either for the bit line coming from the left or the bit line coming from the right, depending on the activated word line, which is often referred to as shared SA concept in literature. During the activation of a word line in a certain block of the memory field, such as an array block, the bit lines of this block are provided with a voltage signal. All other array blocks remain in the deactivated state.

According to the above embodiments, the stress between adjacent bit lines has been made more effective. Thereby, a method has been used to increase the clock ratio between the active and the inactive state of the bit lines during the burn-in compared to the regular access per test mode. In the normal operation, the read amplifier 7b is connected only to the array block with activated word line. Via a signal ISO_{active}, the corresponding NFET transistors 36a-d between the bit lines and the read amplifier 7a-d have been selected. Only in that array block, the bit lines are provided with a voltage difference. At the same time, the transistors lying on the opposite side of the read amplifier 7a-d are turned off via the signal ISO_{adjacent}. And all bit lines in the adjacent array block remain on the same potential. Now, for improved artificial aging of the chips according to the above embodiments, the connection to the adjacent array block has been established with a time delay. Thereby, the same voltage difference has been set up between adjacent bit lines as in the actually activated array block. The time delay can thereby be about 10 nanoseconds and ensure that the read process in the active array block is not interfered with.

The above-described time delay could preferably also be between 5 ns and 20 ns to not interfere with the read out process from the activated array block.

By introducing this test mode, stress between bit lines during burn-in is accelerated by, for example, a factor of 2. This advantage can either be used for quality improvement or for test time savings, which corresponds to a productivity improvement.

Particularly, it should be noted that depending on the circumstances the inventive scheme can also be implemented in software. The implementation can also be carried out in a digital memory medium, particularly a disc or a CD with electronically readable control signals, which can cooperate with a programmable computer system such that the corresponding method is executed. Thus, generally, the invention consists also of a computer program product with a program code for performing the inventive method stored on a machine-readable carrier, when the computer program product runs on a computer. In other words, the invention can also be realized as computer program with program code for performing the method when the computer program runs on a computer.

While this invention has been described in terms of several preferred embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

What is claimed is:

1. An apparatus for aging a chip, comprising:
a first bit line connected to a first memory cell;
a second bit line connected to a second memory cell;
an access element for accessing the first memory cell via the first bit line and for accessing the second memory cell via the second bit line;
a first controllable element for selectively connecting/disconnecting the first bit line to the access element and from the access element, respectively;
a second controllable element for selectively connecting/disconnecting the second bit line to the access element and from the access element, respectively;
a normal operating mode controller for controlling the first and second controllable element, wherein the normal operating mode controller is formed such to select the first controllable element in a normal operating mode for accessing the first memory cell, and to connect the access element to the first bit line, while the second controllable element is controlled to disconnect the access element from the second bit line;
an aging mode controller for controlling the first and second controllable elements, wherein the aging mode controller is formed to control the first controllable element and the second controllable element in an aging mode such that the access element is connected to the first and second bit lines for a predetermined time period.

2. The apparatus according to claim 1, wherein the access element is a read amplifier.

3. The apparatus according to claim 1, wherein several access elements are disposed in stripe-shaped fields on the chip.

4. The apparatus according to claim 1, wherein two bit lines connected to the access element run in opposite directions.

5. The apparatus according to claim 1, wherein the aging mode controller is formed to control the first and second controllable elements in the aging mode such that the first controllable element connects the access element to the first and second bit lines between 5 ns and 20 ns after the second controllable element.

6. The apparatus according to claim 5, wherein the aging mode controller is formed to control the first and second controllable elements in the aging mode such that the first controllable element connects the access element to the first and second bit lines between 8 ns and 12 ns after the second controllable element.

7. The apparatus according to claim 1, wherein the memory cells are volatile.

8. The apparatus according to claim 7, wherein the memory cells are DRAM cells.

9. The apparatus according to claim 1, wherein the memory cells are arranged in rows and columns.

10. The apparatus according to claim 1, wherein the chip further comprises a word line and the normal operating mode controller is formed to address the memory cell via the word line for access.

11. The apparatus according to claim 10, wherein the normal operating mode controller is formed such that during selecting one of the word lines, the controllable units are selected such that a predefined configuration of bit lines is connected to the access element.

12. The apparatus according to claim 1, wherein the aging mode controller puts the chip into the aging mode upon a signal from an external device.

13. The apparatus according to claim 1, wherein the chip is housed.

14. The apparatus according to claim 1, wherein the chip is formed from a wafer.

15. A method for aging a chip, comprising:
a first bit line connected to a first memory cell;
a second bit line connected to a second memory cell;
an access element for accessing the first memory cell via the first bit line and for accessing the second memory cell via the second bit line;
a first controllable element for selectively connecting/disconnecting the first bit line to the access element and from the access element, respectively;
a second controllable element for selectively connecting/disconnecting the second bit line to the access element and from the access element, respectively;
a normal operating mode controller for controlling the first and second controllable elements, wherein the normal operating mode controller is formed such to select the first controllable element in a normal operating mode for accessing the first memory cell, and to connect the access element to the first bit line, while the second controllable element is controlled to disconnect the access element from the second bit line;
wherein the method comprises:
selecting an aging mode controller for controlling the first and second controllable elements, so that the first and second controllable elements are selected such that the access element is connected to the first and second bit lines for a predetermined time period.

16. Computer program with a program code for performing the method for aging a chip, comprising:
a first bit line connected to a first memory cell;
a second bit line connected to a second memory cell;
an access element for accessing the first memory cell via the first bit line and for accessing the second memory cell via the second bit line;
a first controllable element for selectively connecting/disconnecting the first bit line to the access element and from the access element, respectively;
a second controllable element for selectively connecting/disconnecting the second bit line to the access element and from the access element, respectively;
a normal operating mode controller for controlling the first and second controllable elements, wherein the normal operating mode controller is formed such to select the first controllable element in a normal operating mode for accessing the first memory cell, and to connect the access element to the first bit line, while the second controllable element is controlled to disconnect the access element from the second bit line;
wherein the method comprises:
selecting an aging mode controller for controlling the first and second controllable elements, so that the first and second controllable elements are selected such that the access element is connected to the first and second bit lines for a predetermined time period, when the computer program runs on a computer.
